(19) United States
(12) Patent Application Publication
(10) Pub. No.: US 2004/0000898 A1
(43) Pub. Date: Jan. 1, 2004

(54) Method and apparatus for identifying, locating and tracing wires in a multiple wire electrical system

(75) Inventors: Joel E. Pool, Bethesda, MD (US); David W. Thomas, Sante Fe, NM (US); Lee F. Parker, Turlock, CA (US)

Correspondence Address: EDELL, SHAPIRO, FINNAN & LYTLE, LLC, 1901 RESEARCH BOULEVARD, SUITE 400, ROCKVILLE, MD, 20850, US

(73) Assignee: Trace Technologies, Inc., Bethesda, MD (US)

(21) Appl. No.: 10/183,546

(22) Filed: Jun. 28, 2002

(51) Int. Cl. G01R 19/00

(52) U.S. Cl. 324/66

(57) ABSTRACT

A plurality of signal generators and a probe are used to identify, locate and trace a large number of wires in a multiple wire electrical system. Each wire to be traced is electronically marked with a signal generated by a signal generator coupled to the wire in which the signal is unique among a plurality of signal generators. Generated signals are uniquely distinguishable based upon their unique physical characteristics, inclusion of a unique identifier and/or inclusion of a unique voice message. Unique voice messages can be dynamically recorded by the user or synthetically generated. A non-contact signal receiver, or probe, detects and traces the signals emitted from the electronically marked wires. Based upon the unique characteristics of a generated signal or upon a unique identifier within the signal, the signal is identified by the probe and the wire is located.

### BACKGROUND OF THE INVENTION

1. Field of the Invention

The present invention pertains to electrical test equipment. In particular, the invention pertains to methods and apparatuses used to identify, locate and trace wires in a multiple wire electrical system.

2. Description of the Related Art

Electrical wiring systems often include multiple wires extending from a central, convergent location to multiple dispersed remote locations. Such multiple wire electrical systems support local area telephone systems, local area data communication networks (LANs), home automation and alarm systems, industrial control systems and others. Connecting equipment at the central location to devices at the remote locations typically requires technicians to trace wires from the remote locations to their terminations at the central location so that the connectivity of the wire is clearly known. That is, so the technician can determine which wires at the central location run to which remote locations. Such a task can involve tracing hundreds of wires so that the hundreds of wire ends terminating at the central location can be labeled in a meaningful manner, thereby allowing the wires to be properly connected to equipment at the central location. This is a cumbersome process, often requiring many hours of repetitive work by two or more technicians.

In conventional tone tracing systems, a tone generating signal generator is temporarily connected to the end of a wire at a remote location, to generate a signal on that wire. At the central location, such as a network hub equipment room, a wire that carries the signal is located using an inductive probe that emits an audible tone upon detecting the signal that emanates from the wire carrying the signal. The volume of this audible tone is often proportional to the strength of the received signal (and thus proportional to the proximity of the inductive probe to the wire carrying the signal). As the technician moves the probe closer to, or further from, the wire carrying a signal, the volume of the audible tone typically increases or decreases, respectively. This approach allows a technician to locate the wire carrying the signal.

FIG. 1 is a pictorial overview of conventional tone tracing techniques currently used in a typical operational environment to trace LAN wires from individual computer users' offices (e.g., on multiple floors of an office building) to a central network equipment room. First, as shown in operation 110, a technician attaches a signal generator, capable of outputting a single signal (represented in FIG. 1 as signal “A”), to a first network wire terminating within a first office (e.g., third floor, room-301). Next, as shown in operation 120, the technician relocates to a central equipment room (e.g., the building basement) where the opposite end of the wire is believed to terminate and, using an inductive probe having a speaker, listens for the tone generated by the signal generator to locate and then physically tag the opposite end of the electronically marked wire. Then, as shown in operation 130, because the signal generator is capable of generating only a single signal (i.e., signal “A”) the technician must return to the first location to retrieve the signal generator so that it can be used to mark a wire terminating at second office (e.g., third floor, room-302), again returning to the equipment room, as shown in operation 140, to locate and physically tag the second electronically marked wire. These operations are performed by a lone technician traveling back and forth between the central and the respective remote locations, or by a second technician in radio contact with a technician at the central location. However, operations 130 and 140 must be repeated for each subsequent wire to be traced. As a result, tracing a large number of wires is a labor intensive, time consuming and, therefore, expensive task.

A conventional technique for identifying a plurality of wires in a multiple wire electrical system is described in U.S. Pat. No. 4,578,636. There, a resistor is attached between the two remote ends of a wire-pair at multiple remote locations. Each resistor has a different fixed resistance value and each resistive value is associated with an identifier. At the central location, a voltage detecting device is coupled across each wire pair, in turn, to identify the connected resistor based upon the voltage drop detected across the wire pair.

This discrete resistor based approach, however, has significant deficiencies. First, the approach requires a closed circuit, making it difficult to implement in cases where only a single conductor connects the central location with a remote location. The unavailability of a reliable ground, in such a case, can significantly affect the practicality of such an approach. Second, the discrete resistor based approach requires the technician to know, in advance, the precise location of each designated wire at the central location, or to laboriously connect the detector to each wire at the central location in turn (possibly involving hundreds or thousands of wires), in order to locate the designated wires. Such contact-based identification systems therefore cannot locate designated wires at the central location, as quickly or as conveniently as a non-contact, proximity-based tone tracing system.

Another conventional technique for identifying wires in a multiple wire electrical system, described in U.S. Pat. No. 5,557,651, involves use of signal generators coupled to the respective wires as previously described, in which each signal generator can generate a signal composed of different combinations of fixed frequency signal segments in the audible frequency range. This technique allows each wire to be identified at the central location by the composite tone pattern detected using an inductive probe that emits an audible signal based upon the signal detected. A deficiency with this technique is that the inductive probe used to detect the composite tone at the central location is unable to filter out unwanted signals. If more than one signal generator is used to mark a plurality of wires that all lead to a central location within close proximity of one another, the technician using an inductive probe often has difficulty differentiating between the respective signals because the probe tends to amplify the plurality of signals simultaneously, making it difficult for a technician to locate a single wire. If the technician reduces the sensitivity of the inductive probe to minimize overlapping signal reception, the advantages on a non-contact inductive probe are significantly reduced because the distance from an emitting wire at which the inductive probe notifies the technician of a detection is reduced. Even after reducing the sensitivity of the inductive probe, overlapping signal reception can still occur in environments in which multiple signal emitting wires are in close proximity to one another. The inability to exclude certain emitted signals limits a technician's ability to locate specific wires in a controlled, orderly manner. As the tone combinations become complex, it becomes difficult, if not impossible, for a technician to identify and distinguish the increasingly complex tone sequences.

In an effort to overcome this latter deficiency, U.S. Pat. No. 6,233,558, describes a technique that replaces the complex sequence of audible frequency range tones with synthesized voice signals, in which a separate voice message is broadcast upon separate wires. For example, a signal generator broadcasts the phrase, “one, one, one, etc.,” on a first wire and “two, two, two, etc.,” on a second wire. While this approach resolves the confusion introduced by complex audible tones, several deficiencies exist with this approach as well. First, conventional signal generators associated with the technique are limited with respect to the number of wires they can be used to simultaneously mark, because such signal generators emit only fixed, predefined phrases that are not user configurable. Although some signal generators used in association with this technique have multiple output lines, each line is capable of outputting only a single fixed synthesized speech phrase. Though useful for marking a fixed number of wires at a central location, such multiple line signal generators are not useful for marking multiple wires at multiple remote locations. Furthermore, these multiple line signal generators are limited with respect to the number of wires that they can simultaneously mark.

Hence, there remains a strong need for apparatuses and techniques that allows wires in a multiple wire system to be identified and located quickly and easily, and that eliminates much of the repetitive work associated with conventional tracing and wire identification systems. Further, there is a need to efficiently and cost effectively support the simultaneous electronic marking of a large number of wires at a large number of remote locations and allow electronically marked wires to be located using a non-contact receiver capable of eliminating distortion due to the receipt of multiple simultaneous signals.

### SUMMARY OF THE INVENTION

Therefore, in light of the above, and for other reasons that become apparent when the invention is fully described, the present invention includes methods and apparatuses for identifying a wire among a plurality of wires in a multi-wire environment. Each wire in the multi-wire environment has first and second ends wherein the first ends are located at remote locations. The methods and apparatuses described comprise: enabling each of a plurality of signal generators to generate a signal unique among the plurality of signal generators; attaching each of the plurality of signal generators to the first end of separate ones of the plurality of wires, wherein the plurality of signal generators output said unique signals onto said plurality of wires; configuring a probe to respond to the signal output from the signal generator attached to the wire to be identified; and identifying at a central location the wire carrying the signal output from the selected signal generator by placing the probe in close proximity to the wire to be identified and the probe indicating a response to the signal output from the signal generator attached to the wire to be identified.

A group of signal generators can be used to electronically mark at least an equal number of wires in a multiple wire electrical system, in which each wire is marked with a signal that is unique among the group. Each signal generator within the group of signal generators is capable of emitting a uniquely identifiable signal upon a wire to be marked. The group of signal generators can be used to mark a large number of individual wires at a large number of remote locations, each with a uniquely identifiable signal. The uniquely identifiable signal emitted upon each wire allows each signal to be individually detected and individually traced to the wire carrying the signal using a non-contact signal receiver. The signal generator unit and signal receiver described here, and their method of use, greatly reduce the time and labor required to trace wires from numerous remote locations to one or more central locations at which multiple remote wires converge.

The above and still further features and advantages of the invention will become apparent upon consideration of the following descriptions and descriptive figures of specific embodiments thereof. While these descriptions go into specific details of the invention, it should be understood that variations may and do exist and would be apparent to those skilled in the art based on the descriptions herein.

### BRIEF DESCRIPTION OF THE DRAWINGS

FIG. 1 is a pictorial overview of conventional tone tracing techniques as currently used in a typical operational scenario to electronically mark and trace wires.

FIG. 2 is a pictorial overview of an improved technique to electronically mark and trace wires.

FIG. 3 is a block diagram of a signal generator that generates a uniquely identifiable signal, suitable for use with the technique depicted in FIG. 2.

FIG. 4 is a block diagram of a signal receiver for detecting and tracing electronically marked wires and that includes a human observable alert, suitable for use with the technique depicted in FIG. 2.

FIG. 5 is a flow diagram illustrating a process to mark wires in a multiple wire electrical system using signal generators that generate uniquely identifiable signals.

FIG. 6 is a flow diagram illustrating a process to electronically locate and trace electronically marked wires in a multiple wire electrical system using a signal receiver that detects and traces uniquely identifiable signals.

FIGS. 7A-B depict a signal generator FIG. 7A, with a representative user input device including multiple thumb-wheel buttons FIG. 7B and pressure activated buttons, suitable for configuring the signal generator to emit a unique signal.

FIGS. 8A-B depict a signal receiver FIG. 8A, with a representative user input device including multiple thumb-wheel buttons FIG. 8B and pressure activated buttons, suitable for configuring the signal receiver to receive one or more signals.

FIG. 9 depicts a signal generator with a representative user input device, including an LCD display and pressure actuated buttons, suitable for configuring the signal generator to emit a unique signal.

FIG. 10 depicts a signal receiver with a representative user input device, including an LCD display and pressure actuated buttons, suitable for configuring the signal receiver to receive one or more signals.

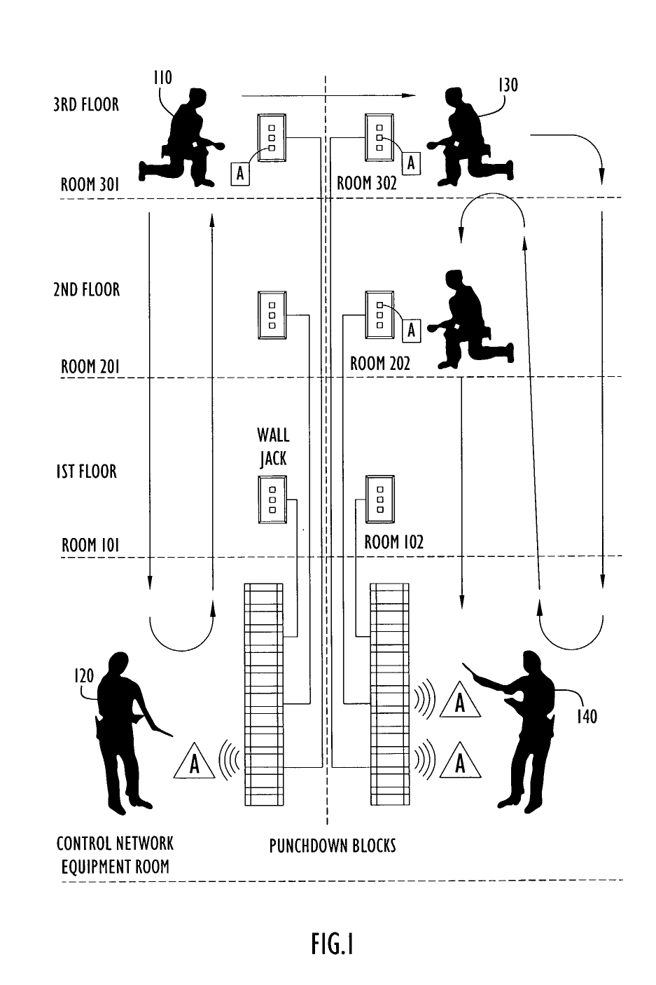

### DETAILED DESCRIPTION

The embodiments described below are described with reference to the above drawings, in which like reference numerals designate like components.

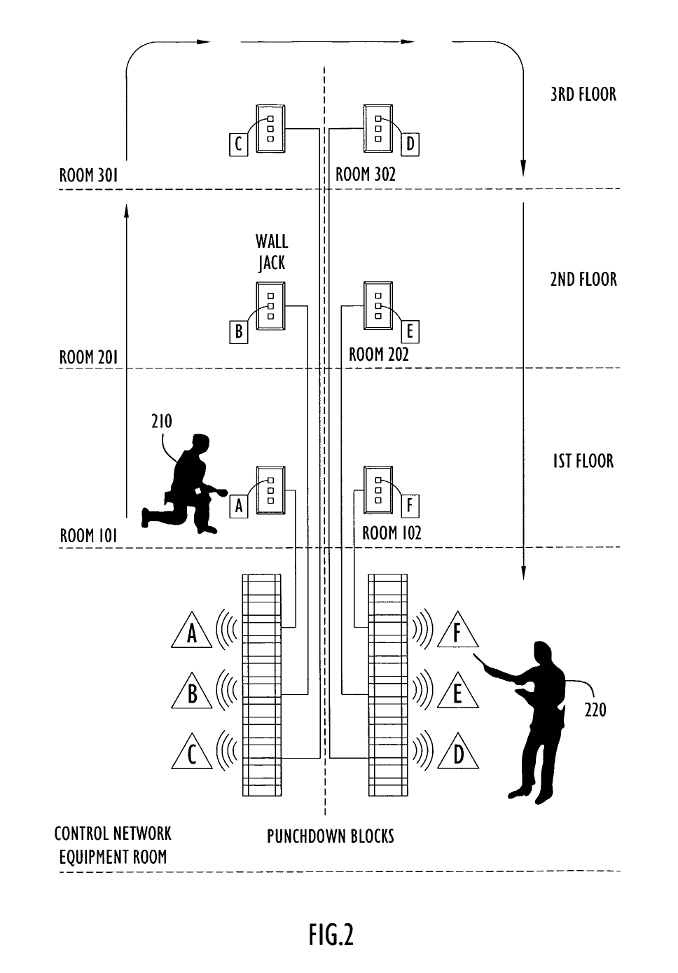

FIG. 2 is a pictorial overview of a technique for electronically marking and tracing a large number of wires using apparatuses and methods described below. First, as shown in operation 210, a technician attaches signal generators, each capable of outputting a single signal uniquely identifiable among the group of signal generators (represented in FIG. 2 as signals “A” through “F”), to a number of wires in the multiple wire electrical system that the technician is interested in tracing. Second, as shown in operation 220, the technician relocates to a central equipment room to electronically locate and physically tag each electronically marked wire based upon the uniquely identifiable signal each wire emits. Depending upon the signal generator/signal receiver combination used, a tuner integrated within a signal receiver, or probe, allows the technician to tune the signal receiver to filter the signals received and to generate a human observable alert responsive only for the signal or group of signals for which the signal receiver is selectively tuned. If the signal generator/signal receiver combination used does not support signal filtering, one or more signal receiver sensitivity controls can be used to selectively detect each of the uniquely identifiable signals based upon unique information contained within the signals and signal strength.

Each signal generator used in the process described above in relation to FIG. 2, emits a signal that is distinguishable between the signals output from the other signal generators used. Signals can be distinguishable based upon physical characteristics of the signal (e.g., time, frequency, or amplitude modulation) and/or based upon information contained within the signal.

One example of such a signal generator is a signal generator capable of generating a signal at one of many selectable frequencies. The user can adjust the signal generator using a thumbwheel switch or other method of selecting a frequency, so that the generator outputs a signal with a frequency unique from other signal generators in use within the same multi-wire environment. A tunable probe can then be tuned to the same frequency as the signal output from the signal generator, so that the probe amplifies and detects only that frequency and alerts the user when a signal of that frequency is detected.

In another non-limiting representative embodiment, a signal generator can generate a unique signal based upon a fixed, or user configurable, unique identifier assigned to the signal generator. A signal generator can generate a unique signal based upon a unique identifier by including the unique identifier within the generated signal and/or by altering physical characteristics of a transmitted signal (e.g., frequency, time or amplitude modulation) based upon the assigned unique identifier. To trace one or more unique signals generated in such a manner, a tunable probe can then be selectively tuned to the same unique identifier assigned to a signal generator currently in use to mark a wire and selectively detect signals configured using the selected unique identifier.

Alternatively, a signal generator can be assigned a voice message that is included within a generated message, thereby making the generated signal unique. Such a voice message can be permanently stored within the signal generator device, or recorded by the user prior to connecting the signal generator to a wire to be traced. Such signals can be traced using a conventional probe based only upon the content of a voice message. A conventional inductive probe, for example, can be used with such signal generators to receive and play the generated voice signals.

The representative, non-limiting techniques, described above, for generating unique signals are not mutually exclusive. For example, a signal generator could use both a unique identifier and a unique voice message to generate a signal that not only contains a unique identifier and a unique voice message, but that also has unique physical characteristics determined by the unique identifier.

As discussed above, a signal generator used in the wire tracing technique illustrated in FIG. 2 can employ different techniques to produce a uniquely identifiable signal. Such signal generators can support the generation of more than one unique signal format, using one or more signal generation techniques. Regardless of the technique used and the format of the uniquely identifiable signal generated, a common characteristic of the generated signals is that they are capable of being individually detected and easily distinguishable from among a large number of simultaneously generated signals, at a central location at which a large number of marked wires converge. This characteristic allows a plurality of signal generators to be connected simultaneously to different wires. This characteristic greatly reduces the time and labor required to trace wires from numerous remote locations to one or more central locations by eliminating the need relocate the respective sources of the generated signals for each measurement.

### Signal Generator Modules

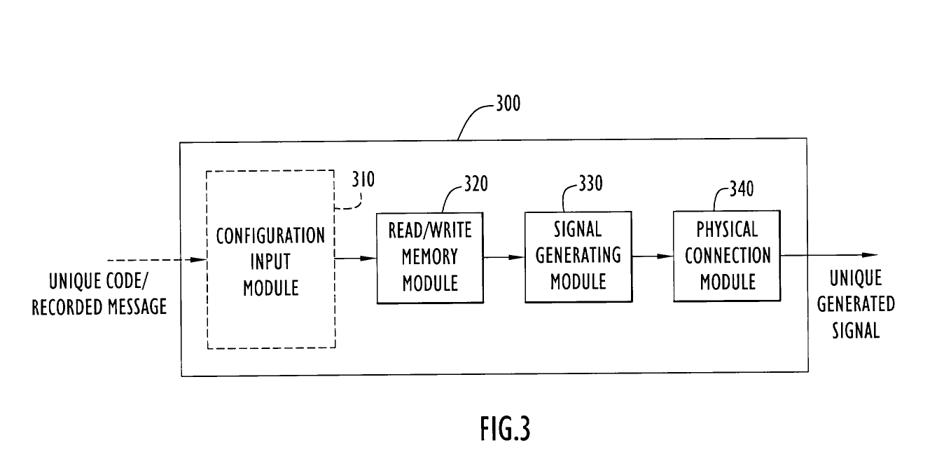

FIG. 3 depicts a non-limiting representative signal generator 300 that includes a configuration input module 310, used to configure the signal generator. The signal generator optionally can include a read/write memory module 320 that can store configuration parameters. A signal generating module 330 accesses the configuration input module to generate signals that are emitted through a physical connection module 340. The signal generating module can also access read/write memory module 320 to read the configuration values and to store temporary values used to generate signals that are emitted through a physical connection module 340.

The configuration input module 310 includes a user interface through which signal generator configuration parameters, such as frequency settings, signal generator unique identifiers or dynamically recorded voice messages can be input. The configuration input module 310 allows a technician to customize the signal generator's operation, such as setting a frequency, or tone, the signal generator will output that operates as the unique identifier, whether the signal generator is to embed its unique identifier within the transmitted signal, whether a recorded voice message, a synthesized voice message based upon the assigned unique identifier, or no voice message is to be transmitted, and/or whether a frequency, time, or amplitude modulated, encoded signal format, or combination of signal formats are to be used for the generated signal.

The physical user interface supported by the configuration input module 310 can include, for example, one or more thumb wheels, pressure actuated switches, or other devices, integrated with the signal generator, by which the user can input configuration parameters and other information into the signal generator. The signal generator can include an LCD display or other visual display, to be used in conjunction with the physical input components of the user interface to allow the user to navigate through menu options, select and set parameters, and to view configuration settings.

In another embodiment of the signal generator, the physical user interface can be contained within a device separate from the signal generator but capable of transferring information to the signal generator via a cable or remote (e.g., infrared) communications interface coupled to the configuration input module. In such an signal generator, the physical interface can be a personal computer, a personal digital assistant (PDA) device, or another device running a software program that allows configuration parameters to be selected and downloaded to the signal generator via one of the non-limiting, representative communications interfaces described above. For example, a signal generator configured to dynamically record a message that is later transmitted as part of the unique signal emitted by the signal generator, can be equipped with a microphone integrated with the signal generator, or the message can be recorded on a separate device and downloaded to the signal generator, as described above. It is noted that configuration input module 310, and its related physical user interface, is optional. For example, signal generators with fixed characteristics established at time of production, do not require a permanently integrated configuration input module 310.

Signal generator configuration parameters, recorded voice messages, and other information can be stored by the signal generator within the read/write memory module 320. In signal generators that include a configuration input module 310 and a read/write memory module 320, the read/write memory module receives and stores configuration parameters from the input module. In signal generators with fixed configurations, configuration information can be stored at time of production via the equivalent of a configuration input module 310 that is not included as part of the final signal generator product in order to reduce signal generator complexity and cost. The need for a memory and its size required to support the respective signal generators varies, depending upon the features supported. For example, a signal generator capable of supporting multiple output signal formats, each with configurable parameters, requires more memory than a signal generator that supports a single fixed signal format. Furthermore, a signal generator that supports dynamic voice recordings requires sufficient memory to store the voice message for later transmission. Alternatively, in at least one non-limiting representative embodiment, memory module memory requirements may be greatly reduced, or eliminated. For example, in a frequency-tunable signal generator embodiment, the signal generator can be tuned to output a specific frequency using an analog setting device, such as a thumb-wheel switch connected to a variable resistor, a variable inductor, a variable capacitor, or similar analog device. In such an embodiment, in which setting an analog device to a unique position causes the signal generator to emit a unique signal, the analog device serves a role equivalent to that of the digital memory module described above, although read/write memory is not required.

When activated, the signal generator's signal generating module 330 retrieves configuration parameter set by the generator's configuration switches or that are stored within the signal generator's read/write memory module 320 (or stored using an analog input device, as described above) and generates an output signal based upon the parameters retrieved.

Referring again to FIG. 3, the signal generator unit 300 contains a physical connection module 340 that allows the signal generator to connect to a wire via a variety of physical connections, that can include a variety of interchangeable standard plug interfaces, alligator clips, inductive hookups, or standard connectors such as a connector suitable for plugging into an RJ-11 or RJ-45 jack, thereby allowing the signal generator unit to output its unique generated signal upon a wire. The physical connection module 340 amplifies the generated signal to a level suitable for it to propagate along the entire length of the wire and so that the wire emits a signal of sufficient energy to be detected by a non-contact signal receiver.

### Generating Unique Signals—With Voice Messages

Signals generated by the signal generating module 330, based upon the configuration parameters retrieved, can include, for example, a synthesized voice message that repeatedly pronounces the unique identifier assigned to the signal generator. Another example of a generated signal is a unique voice message recorded by the user via the configuration input module 310, as described above. Given that each signal is distinguishably unique, because of the unique voice message contained in the signal, the signal can be identified at the central location by the technician listening to the unique voice messages received by a probe. Such signal generators do not require that the signal generator's unique identifier be included within the transmitted signal. These voice message based tracing techniques have the advantage over conventional tone tracing techniques in that a large number of wires can be traced, simultaneously, yet the technique remains compatible with inductive probes currently in widespread use.

The effort required to manually trace wires in a multiple wire environment is greatly reduced using a signal generator that transmits a dynamically recorded user message (e.g., the floor, room and port number to which the signal generator is connected). The ability to dynamically record a technician's voice message, associate the voice message with a remote location, and use that voice message at a central location to assist in locating and identifying a wire offers many operational advantages, that include but are not limited to:

Elimination of the need to memorize or write down a reference table indicating which signal generators are associated with which wires, since descriptive information about each wire's origination point (e.g. “kitchen,” “conference room,” “room 226”) is part of the spoken message inserted on the wire by the signal generator.

Support for a large number of informational formats and permutations, since the user's own spoken information is used.

Removal of all language barriers and speech comprehension issues, since the user's own speech is used.

Quick and repeated reprogramming (re-recording) at the job site with minimal effort, offering unlimited adaptability.

Signals can remain compatible with the inductive probes currently in widespread use.

As previously described, a dynamically recorded voice message, that is a voice message that is recorded by a user, can be supported by a signal generator, regardless of technique used to make its signal uniquely identifiable, as previously discussed. In one non-limiting representative embodiment, generated signals can be unique, and thereby uniquely identifiable, based solely upon their respective unique voice messages.

### Generating Unique Signals—Without Voice Messages

In some multiple wire environments, such as those in which the concentration of wires at the central convergent location is very dense, it may become necessary for the signal generators to emit signals that allow a signal receiver, operated by the technician at the central location, to locate and trace electronically marked wires, to be tuned to selectively receive one or more of the generated signals. This can be achieved by encoding the signal generator's unique identifier within the generated signal, or by using the signal generator's unique identifier to determine the physical characteristics of the transmitted signal in the form of time, frequency, amplitude modulation, etc.

Such a signal tracing technique, using signal generators that output unique signals, has an advantage over conventional tone tracing techniques in that a large number of wires can be traced, yet individual signals can be selectively detected by the signal receiver, allowing the wires carrying a signal to be located and traced in a more controlled manner.

A unique identifier assigned to a signal generator, as described above, is not limited to any single format or length. For example, depending upon the signal generator, a unique identifier can be implemented in a wide variety of formats, such as a unique numeric value, an alphanumeric string, or a pseudo-random noise (PN) code. A unique identifier does not need to remain constant and can be changed over time. For example, the unique identifier can be based directly upon the date/time (e.g., day/hour/sec) that a signal generator is activated for use at a remote location, or can be the result of a random number generator that uses the date/time at which the signal generator is activated as a seed value to generate a unique identifier. Alternatively, a unique identifier can be directly entered by a technician via the signal generator's configuration input module.

A unique identifier is not limited to an abstract value stored in memory. For example, in one non-limiting representative embodiment, the unique identifier can be an actual assigned frequency of a signal to be transmitted by the signal generator. Furthermore, the manner in which the unique identifier is stored is not limited to values stored in digital memory. For example, in one non-limiting representative embodiment, the unique identifier can be an analog setting on an analog input device such as a thumb-wheel connected to a variable resistor, capacitor, inductor, or similar analog device, that directly or indirectly results in the signal generator emitting a unique signal.

### Signals with Unique Physical Characteristics

As discussed above, certain signal generators are capable of generating unique signals that do not include voice messages. One way to generate unique signals among a plurality of signal generators is to use the signal generator's unique identifier to determine the physical characteristics of the transmitted signal in the form of time, frequency, amplitude modulation, etc.

A non-limiting representative signal generator can generate a signal with a frequency that is based upon a numeric value derived from the signal generator's unique identifier using a linear function such as that set forth in equation 1, below.

Signal Freq.=M*f(UI)+B Eq. (1)

where M is a constant;

where f(UI) is a unique numeric value derived from the signal generator's unique identifier; and

where B is a constant.

Using equation (1) above, a unique frequency is calculated, based upon each signal generator's respective unique identifier (UI). In equation (1), above, the function f(UI) is a translation function that generates a unique numeric value based upon the signal generator's unique identifier (UF). As previously discussed, a signal generator's unique identifier is not restricted to a numeric value, but can also include alphanumeric strings, and other formats. The nature of the function f(UI) is determined by the format of the unique identifier. The function f(UI) translates the unique identifier from its original format to a numeric value for use in the above equation. In one non-limiting representative embodiment, if a unique identifier is already represented as a numeric value that is appropriate for use in calculating a signal frequency, no f(UI) translation is required. In another non-limiting representative embodiment, if the unique identifier is a unique assigned value, appropriate for use as a signal frequency, no f(UI) translation is required and in equation (1), M=1 and B=0.

By way of a second non-limiting example, another equation, such as equation (2), below, is used to determine a time interval the signal generator uses to switch between two or more fixed frequencies.

Freq. duration=1/M*f(UI) Eq. (2)

where M is a constant; and

where f(UI) is a unique numeric value derived from the signal generator's unique identifier (UI).

Using equation (2) above, a time period is calculated, based upon each signal generator's unique identifier. The function f(UI) in equation (2) performs a translation to convert the unique identifier to a numeric value, if required, as described above in relation to equation (1). If such a physical signal format is used to mark a wire, a signal receiver measures the duration between frequency shifts to identify the unique identifier associated with the signal.

As demonstrated above, transmitted signal characteristics can be uniformly manipulated in a group of signal generators composed of a large number of independently operating, yet similarly configured, signal generators. The signal generators in the group generate a large number of signals, based upon their respectively assigned unique identifiers, that are unique within the group. A receiver can be tuned to individually detect each unique signal from among a multitude of similar signals.

### Signals with Encoded Unique Identifiers

In addition to the techniques described above, a signal generator's unique identifier can be encoded within a transmitted signal based upon any number of well known transmission protocols and signal formats. As previously described, the signals generator's unique identifier can be of any length and/or combination of values, as long as it is unique among the other signal generators within a group of signal generators being used in a facility. The unique identifier allows the signal generator to assure that any signal that includes the unique identifier within a generated signal, and/or that uses the unique identifier to establish unique physical characteristics, is unique. Regardless of the transmission protocol and signal format used, the receiving unit selectively receives only the unique signals for which it is tuned. Such a tuned receiving unit at a central location emits a human observable alert only upon detection of a signal for which it is tuned. Such approaches, that generate uniquely identifiable signals, allow technicians to individually trace wires in a controlled and orderly manner.

### Signal Receiver/Probe

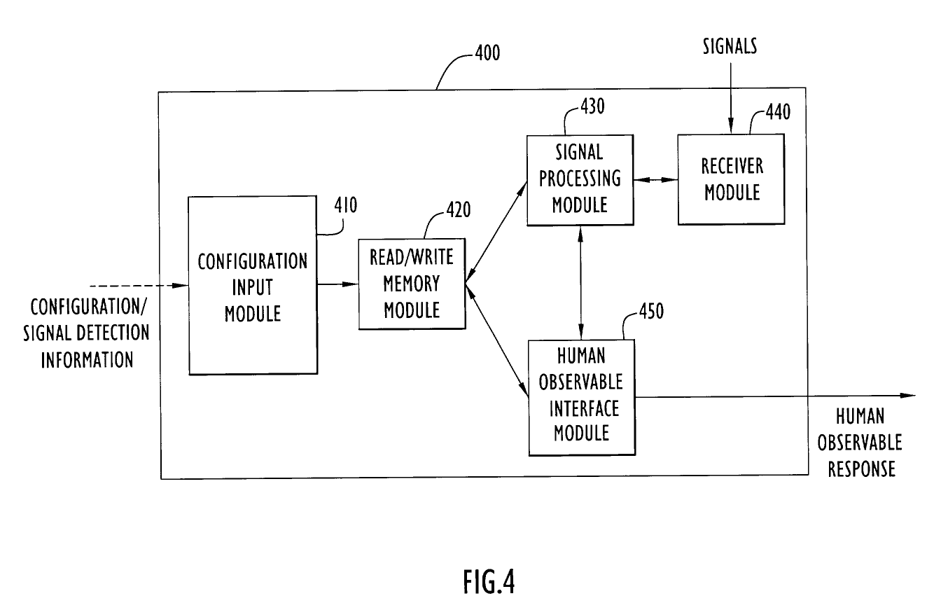

FIG. 4 is a non-limiting representation of a signal receiver 400, that includes a configuration input module 410 used to change and store configuration parameters in an optional read/write memory module 420. A signal processing module 430 receives signals from a receiver module 440 that detects and receives physical signals from the outside environment. Upon notification from the signal processing module 430 that a signal has been received, a human observable alert module 450 emits a human observable alert that a technician uses to locate and trace the electronically marked wire of interest.

Similar to the signal generator, the signal receiver includes a configuration input module 410 that allows the technician to specify a signal format to be detected and/or allows the technician to tune the receiver to detect one or more specific signals, based upon unique physical characteristics or unique identifiers encoded within the signal. In addition, the configuration input module 410 can be used to specify the type of physical signal to be received (e.g., specify a specific frequency, time, amplitude modulation format and/or encoding scheme and unique identifier(s) of the signal(s) to be received), whether a voice message is included in the received signal, and the type of human observable response that is issued upon detection of a signal for which the signal receiver is tuned.

The physical user interface supported by the signal receiver configuration input module 410 includes a selection device, such as one or more thumb wheels, pressure actuated switches, or other types of switches integrated with the signal receiver, by which the user can input configuration information into the signal receiver. The configuration input module 410 can include an LCD display or other visual display in conjunction with the selection device to allow the user to navigate through menu options, and to select and set parameters, and to view configuration settings. As with the signal generator, the physical user interface for the signal receiver can be contained within a device separate from the signal receiver but capable of transferring information to the signal receiver via a cable or infrared communications interface. In such a signal receiver, the physical interface can be a personal computer or personal digital assistant (PDA) device, or another device running a software program that allows configuration parameters to be selected and downloaded to the signal receiver via a communications interface, as previously described.

Configuration parameters input to the signal receiver via the configuration input module 410 can be stored within a read/write memory module 420. When activated, the signal receiver's signal processing module 430 retrieves the configuration parameters from the read/write memory module 420 and configures itself to detect a signal of the nature defined within the configuration parameters. By way of non-limiting example, the signal processing module 430 may ascertain, based upon fixed or configurable parameters retrieved from the memory module 420, that it should locate a frequency modulated signal with certain characteristics. Once the nature of the signal to be received is known, the memory module 420 notifies the signal processing module 430 of subsequent changes in the stored memory variables so that the signal processing module can reconfigure itself to detect the newly specified characteristics of the signal(s) it should detect.

For example, in one non-limiting representative signal receiver, the read/write memory module 420 informs the signal processing module 430 every time a technician changes a parameter that effects the nature of the signal(s) the receiver is to detect. In another non-limiting representative signal receiver that supports multiple signal types, the primary characteristics of several signal formats and transmission protocols are pre-configured and stored within the memory module 420. In such a signal receiver a technician uses the configuration input module 410 to select a signal type. At a central location to detect signals, the technician tunes the signal to selectively receive one or more signals by specifying one or more unique identifier(s) associated with a subset of signal generators in use. In a third nonlimiting representative signal receiver, user recorded messages are recorded via a microphone integrated with the signal receiver and the messages are stored within the memory module 420 in association with a specific signal generator unique identifier. Upon detection of a signal containing the unique identifier, the signal receiver outputs a human observable alert containing the recorded voice message.

Read/write memory requirements for the read/write memory module 420 can vary significantly. For example, a signal receiver configurable to support multiple signal formats (e.g., various forms of frequency/time/amplitude modulated signals and/or various forms of encoded signals), or a signal receiver capable of recording user voice messages, will require more memory than a signal receiver that does not support such features. Alternatively, as previously addressed with respect to signal generator memory requirements, in some nonlimiting representative signal receiver embodiments, memory module memory requirements may be greatly reduced, or eliminated. For example, in a frequency-tunable signal receiver embodiment, the signal receiver can be tuned to receive a unique frequency using an analog input device, such as a thumb-wheel switch connected to a variable resistor, a variable inductor, a variable capacitor, or similar analog device. In such an embodiment, in which setting an analog device to a unique position causes the signal receiver to receive a unique signal, the analog device serves in a role equivalent to that of the digital memory module described above, although read/write memory is not required.

Signals from the wires are received via a receiver module 440 and sent to the signal processing module 430 for processing. In some signal receivers, the signal processing module 430 processes configuration parameters retrieved from the memory module 420 to derive configuration parameters that the signal processing module 430 sends to the receiver module 440 to facilitate the receipt of incoming signals. For example, if the signal is time or frequency modulated, it may be more efficient to perform a portion of the filtering with conventional hardware implemented in the receiver module 440. In such a case, the signal processing module 430 calculates optimal processing parameters, using pre-programmed signal processing techniques and/or dynamically programmed algorithms retrieved from the memory module 420, and sends them to the receiver module 440. In another signal receiver, the receiver module 440 receives and down-converts a fixed signal type and passes the signal to the signal processor for further processing, such as to decode an encoded signal.

Upon detection of a signal for which the signal generator is tuned, the signal processing module 430 notifies the Human Observable Alert (HOA) module 450 of the detection and sends the HOA module 450 an indication of the strength of the signal received. The HOA module 450 is responsible for providing an audible, visual, and/or vibratory response that alerts the technician that the receiver has detected a signal for which it has been tuned. The strength of the alert issued is dependent upon the strength of the signal received. For example, one signal receiver allows a technician to set a sensitivity threshold via the configuration input module 410 using a sensitivity control dial or pressure actuated keys to selectively increase or decrease the intensity of an audible, visual, and/or vibratory alert in response to the strength of a detected signal. Such a setting is dynamically configurable to meet individual user/environment requirements and the strength of the respective signals received at a specific location.

The HOA module 450 alert can include a voice message alert. Voice message alerts are audible broadcasts of voice messages transmitted within the signal received, synthesized messages generated by the HOA module 450 upon notification from the signal processing module 430 that a signal associated with a specific unique identifier has been received, or a user recorded message stored within the memory module 420 and included within the human observable alert message upon detection of a signal containing the unique identifier with which the user recorded message is associated.

The HOA module 450 can also be configured to generate non-verbal alerts. Upon notification from the signal processing module 430 that a signal for which the signal receiver is tuned has been detected, the HOA module 450 outputs high or low pitched tones, slow or rapid beeps or chirps, based upon configuration parameters retrieved from the memory module 420. Such alert configuration parameters can be pre-set or configured by a technician via the configuration input module 410 to create an alert that includes any combination of audible alerts (including tone or voice), visual alerts (including light emitting diode (LED) displays or liquid crystal displays (LCD)), vibratory alerts, or any and all of the above.

The HOA module can facilitate locating wires marked with uniquely identifiable signals based upon the strength of the signals detected, even if the signal generator/signal receiver combination used does not support filtering of unique signals. For example, in one non-limiting representative signal receiver embodiment, a preset or user configurable sensitivity setting is used to establish a signal strength threshold at or above which a human observable alert is issued. In another non-limiting representative embodiment a preset or user configurable sensitivity setting is used to control the strength of a human observable alert issued in response to detection of a unique signal. In yet another non-limiting representative embodiment, both a signal strength threshold setting and a human observable alert setting are used. In such a non-limiting representative embodiment, the human observable alert is preferably proportional to the strength of the received signal above the established signal strength threshold and the intensity of the alert is scaled in proportion to the human observable alert sensitivity setting. Either setting may be fixed or user configurable.

HOA module 450 visual alerts can include, but are not limited to, visual signal strength displays via a series of LEDs, an LCD, a graphical output, analog needle gauge or other visual output device associated with the signal receiver. Human observable alerts assist the user with feedback regarding the detection and proximity of the wire to be located, as previously discussed.

As described above, a human observable alert issued by a receiving unit can be audible, visual, vibratory, or include a combination of any or all of the above. Audible alerts can include, but are not limited to, a user selectable tone or series of tones, a synthesized voice message transmitted by the signal generator based upon the unique identifier assigned, a user recorded message stored within the signal generator and transmitted with the signal, a synthesized voice message generated by the signal receiver based upon the unique identifier of the detected message, or a user recorded message stored within the signal receiver and associated with the unique identifier by the user. Visual alerts can include flashing or sequentially activated lights or LEDs, and LCD or LED displays capable of displaying alphanumeric messages, such as the unique identifier of a detected signal, or graphical messages such as signal strength related visual queues, charts and graphs.

In some cases, a conventional inductive probe can be used to receive the unique signal marking a wire, such as the case where the unique signal is a tone or an analog voice. In those cases, the probe receives and amplifies the tone or voice signal.

### Operational Use

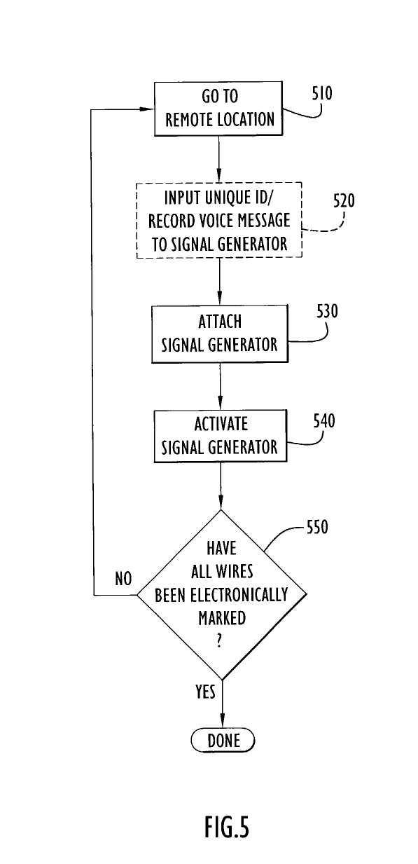

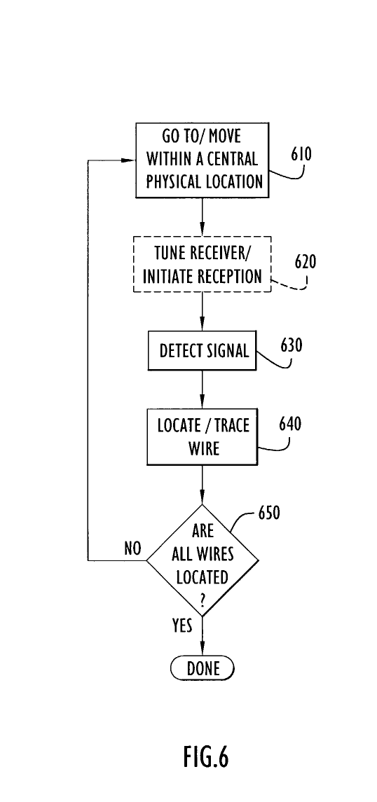

The signal generators and receivers described here allow a large number of wires in a multiple wire electrical system to be electronically marked at multiple remote locations in a manner that allows the same electronically marked wires to be individually located and traced at a central location regardless of the number of marked wires that converge upon the central location. Now that representative signal generators and signal receivers have been introduced, additional detail concerning the operational use of such devices is described in relation to FIG. 5 and FIG. 6.

FIG. 5 is a non-limiting representative flow diagram that illustrates operations for electronically marking wires in a multiple wire electrical system using a signal generator consistent with the signal generator shown in FIG. 3. First, a technician goes to a remote location 510 at which a wire that he wishes to trace is present. An example of such a location is an office on one of the floors of an office building. If the technician uses a configurable signal generator, the technician inputs a unique identifier, records a voice message to be transmitted by the signal generator, and/or configures the signal generator 520 using any of the user configurable parameters previously described that are supported by the specific signal generator in use. If a fixed configuration signal generator is used, the signal generator is pre-configured to output a distinguishably unique voice and/or encoded signal and no on-site configuration is required. Next, the technician attaches the signal generator 530 to a wire the technician wishes to trace, either through a standard plug, alligator clip, needle conductor, or other connector, such as an inductive lead, that allows the signal generated by the signal generator to be coupled onto the wire. Once physically connected to a wire that is to be electronically marked, signal generation is activated 540 so that the generator transmits the signal onto the attached wire. In this manner the attached wire is electronically marked with a signal of sufficient energy to propagate the entire length of the wire and to emanate a unique and detectable signal. If all the wires to be traced are electronically marked 550, the technician completes the process of electronically marking wires. Otherwise, the above process is repeated until all wires to be traced are electronically marked.

FIG. 6 is a non-limiting representative flow diagram that illustrates operations for detecting and locating electronically marked wires in a multiple wire electrical system using a signal receiver, or probe, consistent with the description related to FIG. 4. First, a technician goes to a central location 610 at which electronically marked wires (i.e., marked using techniques discussed in relation to FIG. 5) are believed to converge. An example of such a location is a LAN hub equipment closet, a network/computer equipment room, or telephone equipment/Private Branch Exchange (PBX) closet. If a tunable signal receiver is used, the technician tunes the signal receiver to receive one or more signals 620. This is performed by selecting the appropriate signal format and/or selecting one or more unique identifiers (or logical identifiers, as previously described) via the configuration module user interface, as previously described. In this manner, the signal receiver is configured to generate a human observable alert only in response to detecting a signal for which the receiver has been tuned. However, if a signal generator/signal receiver combination is used that does not support unique signal filtering, the signal receiver is not tuned (as indicated by the dashed box around operation 620). In such a scenario, the technician differentiates signals from other signals, based upon their unique message content alone, using one or more sensitivity settings to separate unique signals based upon signal strength, as previously discussed. Next, the technician attempts to physically detect the emitted signals by physically moving the signal receiver within the confines of the central location until a single signal is detected 630. Once a single signal is detected, the technician uses the varying intensity of the human observable alert to locate and trace the wire carrying the signal until a location on the wire appropriate for physical tagging is found 640. Once all wires to be traced have been located and tagged 650, the process of electronically locating and tracing wires is complete. Otherwise, the above process is repeated until all wires to be traced have been physically located and tagged.

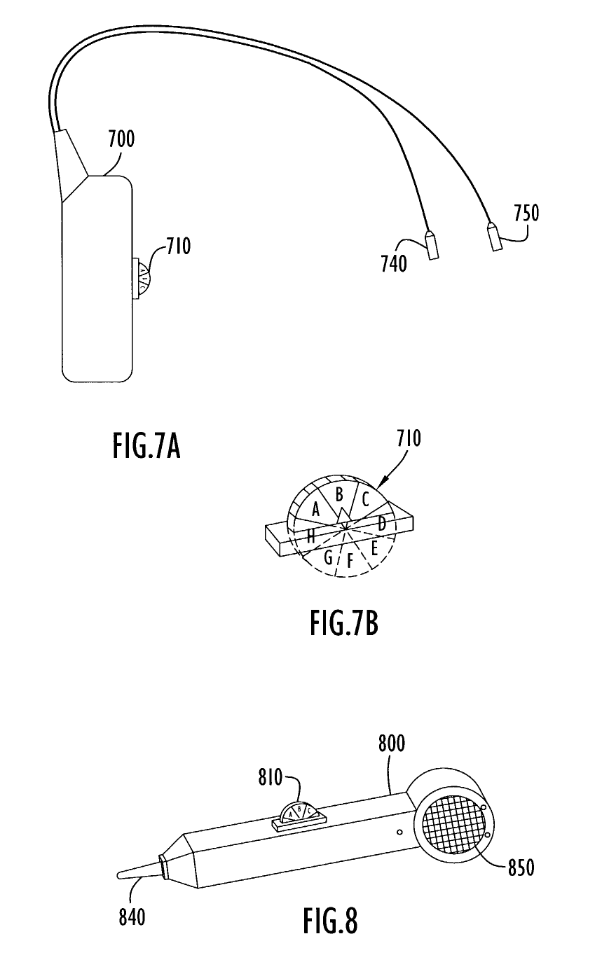

FIG. 7A depicts a non-limiting, representative signal generator 700 in which a thumb-wheel selector 710 is used to configure the signal generator to emit a signal, unique among a group of signal generators, upon a wire coupled to the signal generator via coupling leads 740 and/or 750. For example, in one non-limiting representative embodiment, the thumb-wheel selector 710 can be used to tune a signal generator 700 capable of generating a signal at one of many selectable frequencies to output a signal at a specific frequency. Using the thumbwheel switch 710, a user can select a unique transmission frequency, so that the generator outputs a signal with a frequency unique from other signal generators in use within the same multi-wire environment. Alternatively, in a signal generator configured through the selection of a unique identifier, the thumbwheel switch 710 can be used to select a unique identifier that can be used to generated a unique signal in a variety of ways, as previously discussed. Multiple thumbwheels can be used if necessary. For example, a signal generator with three thumbwheels, each with ten settings, would be capable of one-thousand unique settings. Regardless of the technique used to generate a unique signal, coupling leads 740 and 750 can support multiple interchangeable coupling devices such as CAT-V, alligator clip, inductive coupler, or other coupling devices, that can be used to couple the signal generator to a wire within the multi-wire electrical system so that the signal generated by the signal generator can be output upon the wire.

FIG. 7B depicts a non-limiting, representative thumb-wheel selector 710 that supports eight selectable settings. A technician selects a signal to be emitted by the signal generator that is unique among the signal generators in simultaneous use by selecting a thumb-wheel setting that is different than the thumb-wheel settings on the other signal generators. As previously described, depending upon the number of unique signals supported, multiple thumb-wheel selectors can be used. For example, a signal generator with three thumb-wheels, each with ten positions, is capable of one thousand unique settings.

FIG. 8 depicts a non-limiting, representative signal receiver or probe 800, in which a thumb-wheel selector 810, similar to that depicted in FIG. 7B, is used to tune the signal receiver to receive a unique signal. A technician tunes the signal receiver to receive a signal emitted by a specific activated signal generator by selecting the same thumb-wheel position that is selected on the activated signal generator. When the signal for which the signal receiver is tuned is detected via a receiver antenna 840, an audible alert is emitted via a speaker 850, as previously described. Depending upon the number of unique signals supported, multiple thumb-wheel selectors can be used. For example, a signal receiver with three thumb-wheels, each with ten positions, is capable of one thousand unique settings. In this manner, the probe 800 detects the signal output by the selected signal generator and ignores the signals from the other signal generators.

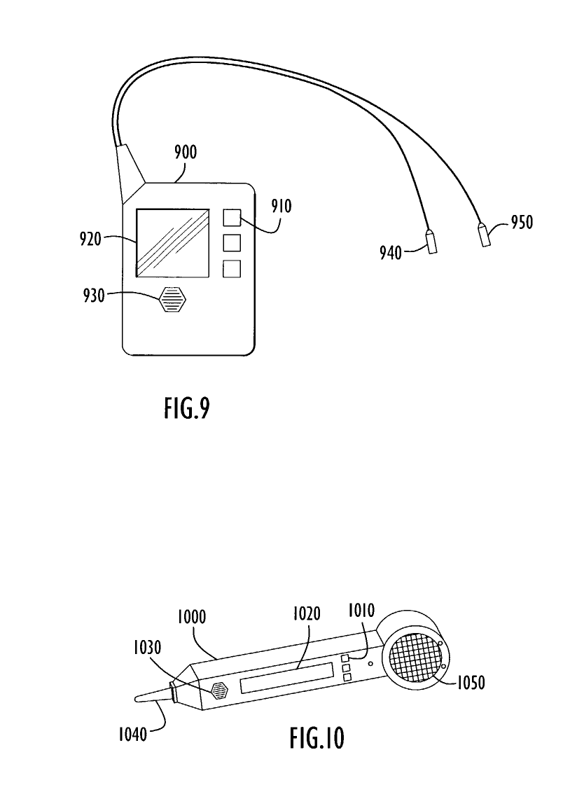

FIG. 9 depicts a non-limiting, representative signal generator 900, in which pressure actuated buttons 910, an LCD display 920, and integrated microphone 930, are used to configure the signal generator to emit a unique signal, that can include a dynamically recorded voice message, upon a wire coupled to the signal generator via coupling leads 940 and/or 950. Coupling leads 940 and 950 can support multiple interchangeable coupling devices such as CAT-V, alligator clip, inductive coupler, or other coupling devices, that can be used to couple the signal generator to a wire within the multi-wire electrical system so that the signal generated by the signal generator can be output upon the wire. A technician uses the pressure actuated buttons to navigate through menus displayed upon the LCD display to select signal formats, to specify unique identifiers, and/or to activate the microphone to record a dynamic voice message that can be transmitted in the unique signal.

FIG. 10 depicts a non-limiting, representative signal receiver, or probe, 1000, in which a technician uses pressure actuated buttons 1010, an LCD display 1020, and an integrated microphone 1030, to tune the signal receiver to receive a specific signal output from one of a plurality of signal generators and to emit a desired human observable alert. Such an alert can include a voice message contained in a received signal or a voice message recorded and stored within the signal receiver and associated with a unique signal, as previously described. A technician tunes the signal receiver to receive the signal emitted by a specific one of the activated signal generators by selecting the same unique signal settings selected upon that activated signal generator. When the signal for which the signal receiver is tuned is detected via the receiver antenna 1040, a human observable alert is emitted via speaker 1050 and/or via the LCD display, as previously described.

Each of the modules addressed with respect to the non-limiting representative signal generator and signal receiver embodiments described above can be implemented to varying degrees within software, hardware, firmware, analog electronic devices, digital electronic devices and/or any combination of the above.

Each of the modules addressed with respect to the non-limiting representative signal generator and signal receiver embodiments described above can be integrated or combined to varying degrees, based upon the features supported and the technology used to implement the respective signal generators or signal receiver devices.

For example, one embodiment uses a frequency-tunable analog signal generator, and a frequency tunable analog inductive amplifier signal receiver. In such an embodiment generated signals are set to be unique among a plurality of signal generators being used based upon their unique frequency and the signal receiver filters generated signals based upon the set frequency. Such an embodiment is an example of a cost effective signal generator and signal receiver.

In the signal generator, for example, the input configuration module and memory module can be implemented using an analog input device, such as a thumb-wheel connected to variable analog circuit component such a variable resistor, variable inductor, or variable capacitor, that is an integral component of the signal generating module. The signal generator is configured to generate a signal with a unique signal frequency by selecting a unique setting on the analog input device. In this manner, a unique setting is established on the variable analog circuit component that causes the signal generating module to generate a signal with a unique signal frequency. This unique signal is amplified and transmitted upon a wire by the physical connection module.

In the signal receiver, the input configuration module and memory module can also be implemented using an analog input device, such as a thumb-wheel connected to variable analog circuit component such a variable resistor, variable inductor, or variable capacitor, that is an integral component of the signal processing module and/or the receiver module. The signal receiver is tuned to receive a signal with a unique signal frequency by selecting a unique setting on the analog input device. In this manner, a unique setting is established on the variable analog circuit component which causes the signal processing module and signal receiver module to detect only those signals with the frequency characteristics for which the signal receiver has been tuned. The human observable alert module, in such an embodiment, can be implemented using an amplifier circuit that amplifies the received signal and outputs the amplified signal to a speaker. Alternatively, the received signal may be used to control a signal output to a set of LEDs, for a visual alert that is proportional to the strength of the signal received. The received signal may also be used to control a signal output to a vibrating device, for a vibratory alert that is proportional to the strength of the signal received.

Having described the new and improved apparatuses and methods for identifying, locating and tracing wires in a multiple wire electrical system, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. A method of identifying a wire among a plurality of wires, each of the plurality of wires having first and second ends, the first ends being located at remote locations, the method comprising:
enabling each of a plurality of signal generators to generate a signal unique among the plurality of signal generators;
attaching each of the plurality of signal generators to the first end of separate ones of the plurality of wires, wherein the plurality of signal generators output said unique signals onto said plurality of wires.

2. The method of claim 1, wherein the unique signal generated by each of the plurality of signal generators is unique based upon a voice message contained within the generated signal.

3. The method of claim 2, wherein said enabling each of the plurality of signal generators to generate a unique signal includes recording the voice message within each signal generator.

4. The method of claim 3, wherein said recording the voice message within each signal generator is performed by a user of the plurality of signal generators.

5. The method of claim 1, wherein the unique signal generated by each of the plurality of signal generators is unique based upon signal frequency.

6. The method of claim 5, wherein said enabling each of the plurality of signal generators to generate a unique signal includes selecting a unique frequency to modulate a portion of the generated signal.

7. The method of claim 1, wherein the unique signal generated by each of the plurality of signal generators is unique based upon a digital code contained within the generated signal.

8. The method of claim 7, wherein said enabling each of the plurality of signal generators to generate a unique signal includes selecting a digital code for inclusion within the generated signal.

9. The method of claim 1, wherein the unique signal generated by each of the plurality of signal generators is unique based upon a unique identifier contained within the generated signal.

10. The method of claim 9, wherein said enabling each of the plurality of signal generators to generate a unique signal includes configuring each signal generator with the unique identifier.

11. The method of claim 10, wherein said unique identifier is at least one of a digital code, a numeric value, an alphanumeric string, a pseudo-random noise code, an analog setting on an analog input device, a voice message, and a signal frequency.

12. The method of claim 1, wherein the unique signal generated by each of the plurality of signal generators has a characteristic that is unique among the signals output from the plurality of signal generators based upon a unique identifier contained within the signal generator.

13. The method of claim 12, wherein said unique identifier is at least one of a digital code, a numeric value, an alphanumeric string, a pseudo-random noise code, an analog setting on an analog input device, a voice message, and a signal frequency.

14. The method of claim 1, further comprising:
configuring a probe to respond to the signal output from the signal generator attached to the wire to be identified; and
identifying the wire carrying the signal output from the selected signal generator by placing the probe in close proximity to the wire to be identified and the probe indicating a response to the signal output from the signal generator attached to the wire to be identified.

15. The method of claim 14, wherein the probe is configurable to respond only to the signal output from the signal generator attached to the wire to be identified.

16. The method of claim 14, wherein configuring the probe includes configuring the probe to receive a signal containing a voice message.

17. The method of claim 14, wherein configuring the probe includes configuring the probe to detect a signal of the same frequency used to modulate a portion of a signal output from the signal generator attached to the wire to be identified.

18. The method of claim 14, wherein the unique signal generated by each of the plurality of signal generators is unique based upon a signal frequency, and wherein configuring the probe includes configuring the probe to receive a signal with the same signal frequency as the signal generated by the signal generator attached to the wire to be identified.

19. The method of claim 18, wherein identifying the wire carrying the signal includes the probe detecting the signal with frequency characteristics for which the probe is configured and generating a human observable alert.

20. The method of claim 14, wherein the unique signal generated by each of the plurality of signal generators is unique based upon a digital code contained within the generated signal, and wherein configuring the probe includes configuring the probe with the same digital code contained within the signal generated by the signal generator attached to the wire to be identified.

21. The method of claim 20, wherein identifying the wire carrying the signal includes the probe detecting the signal containing the digital code for which the probe is configured and generating a human observable alert.

22. The method of claim 14, wherein the unique signal generated by each of the plurality of signal generators is unique based upon a unique identifier contained within the generated signal, and wherein configuring the probe includes configuring the probe with the same unique identifier contained within the signal generated by the signal generator attached to the wire to be identified.

23. The method of claim 22, wherein identifying the wire carrying the signal includes the probe detecting the signal containing the unique identifier for which the probe is configured and generating a human observable alert.

24. The method of claim 14, wherein the unique signal generated by each of the plurality of signal generators has a characteristic that is unique among the signals output from the plurality of signal generators based upon a unique identifier contained within the generated signal, and wherein configuring the probe includes configuring the probe with the same unique identifier contained within the signal generator attached to the wire to be identified.

25. The method of claim 24, wherein identifying the wire carrying the signal includes a configurable probe detecting the signal with physical characteristics associated with the unique identifier for which the probe is configured and generating a human observable alert.

26. A method of locating a wire among a plurality of wires each carrying a tracing signal unique among the signals carried among the plurality of wires, comprising:
configuring a signal receiver to detect a signal unique among the tracing signals;
placing the signal receiver within close proximity to the wire to be located; and
outputting an alert from said signal receiver in response to the signal receiver detecting the unique tracing signal.

27. The method of claim 26, wherein the signal receiver is configurable by tuning the signal receiver to detect a unique frequency of the unique tracing signal.

28. The method of claim 26, wherein configuring the signal receiver to detect the unique tracing signal includes configuring the signal receiver with a digital code assigned to a signal generator attached to the wire to be located.

29. The method of claim 26, wherein the signal receiver is configurable by tuning the signal receiver to detect only a selected one of the unique tracing signals having a same unique identifier as is assigned to a signal generator attached to the wire to be identified.

30. The method of claim 26, wherein the tracing signals each contain a voice message, and said configuring the signal receiver includes configuring a signal receiver to receive a signal containing a voice message.

31. The method of claim 26, wherein said alert output from said signal receiver in response to the signal receiver detecting the unique tracing signal is proportional to the strength of the signal detected.

32. The method of claim 31, wherein the intensity of said alert is adjustable via a user interface.

33. The method of claim 26, wherein said alert output from said signal receiver in response to the signal receiver detecting the unique tracing signal includes at least one of: an audible alert; a visual alert; a voice message; and a vibratory alert.

34. A signal generator for use in identifying a wire within in a multi-wire electrical system, comprising:
a configuration unit suitable for setting a configuration of the signal generator to be unique among a plurality of signal generators;
a signal processing module connected to the configuration unit and configurable to generate a tracing signal unique among the plurality of signal generators, wherein the characteristics of the unique tracing signal are based upon the unique configuration of the signal generator;
a connection module coupled to the signal processing module and configurable to connect the signal generator to the wire and to transmit the unique tracing signal upon the wire.

35. The signal generator of claim 34, wherein the configuration unit includes at least one of an LCD display, a thumbwheel switch, a pressure actuated key, a dip switch, a touch sensitive LCD display, an LED, and a microphone.

36. The signal generator of claim 34, wherein the configuration unit is suitable to set at least one of a unique identifier, a simulated voice message, a voice message and a user recorded voice message.

37. The signal generator of claim 34, wherein the configuration unit is suitable to set a unique identifier including at least one of a numeric value, an alphanumeric string, a pseudo-random noise code, an analog setting on an analog input device, a voice message, and a unique signal frequency.

38. The signal generator of claim 34, wherein the unique output signal generated by the signal processing module includes at least one of a unique identifier and a user recorded voice message.

39. The signal generator of claim 38, wherein the unique identifier is one of a digital code, a numeric value, an alphanumeric string, a pseudo-random noise code, an analog setting on an analog input device, a voice message, and a unique signal frequency.

40. The signal generator of claim 34, wherein the unique output signal generated by the signal processing module includes at least one of a prerecorded voice message and a simulated voice message.

41. The signal generator of claim 34, wherein the unique output signal generated by the signal processing module includes at least one of: modulation characteristics based upon a unique identifier; frequency characteristics based upon a unique identifier; frequency characteristics based upon a unique assigned frequency; and amplitude characteristics based upon a unique identifier.

42. The signal generator of claim 41, wherein the unique identifier is one of a digital code, a numeric value, an alphanumeric string, a pseudo-random noise code, an analog setting on an analog input device, a voice message.

43. A signal receiver for use in locating a wire within in a multi-wire electrical system, comprising:
a configuration unit having a selection device suitable for configuration by a user to specify a unique tracing signal to detect;
a signal receiver module configurable to receive signals from one or more wires and detect only the unique tracing signal specified in the configuration unit;
a human observable alert module configurable to output a human observable alert in response to detection of the unique tracing signal for which the signal receiver is configured to detect.

44. The signal receiver of claim 43, wherein the signal receiver is tunable to receive one of a plurality of tracing signals.

45. The signal receiver of claim 43, wherein the configuration unit includes at least one of an LCD display, a thumbwheel switch, a pressure actuated key, a dip switch, a touch sensitive LCD display, an LED, a microphone, and a speaker.

46. The signal receiver of claim 43, wherein the configuration unit is suitable to specify a unique signal for detection based upon at least one of a digital code, a unique identifier, a unique signal frequency, a unique amplitude modulation, and a voice message.

47. The signal receiver of claim 46, wherein the unique identifier includes at least one of a numeric value, an alphanumeric string, a pseudo-random noise code, an analog setting on an analog input device, a voice message, and a unique signal frequency.

48. The signal receiver of claim 43, wherein the unique signal detected by the signal receiver module includes at least one of a digital code, a unique identifier, voice message, a prerecorded voice message, and a user recorded voice message.

49. The signal receiver of claim 43, wherein the unique signal detected by the signal receiver module includes at least one of a simulated voice message, modulation characteristics based upon a unique identifier, frequency characteristics based upon a unique identifier, frequency characteristics based upon a unique assigned frequency, and amplitude characteristics based upon a unique identifier.

50. The signal receiver of claim 43, wherein the alert from the human observable alert module includes at least one of an audible alert, a visual alert, a voice message, and a vibratory alert.

51. The signal receiver of claim 50, wherein said visual alert comprises: flashing lights; sequentially activated lights; flashing LEDs; sequentially activated LEDs; display of alphanumeric messages presented via an LCD display; display of graphical messages presented via an LCD display; display of alphanumeric messages presented via an LED display; and display of graphical messages presented via an LED display.

52. The signal receiver of claim 51, wherein said visual alert further comprises an alphanumeric display containing the unique identifier of a detected signal.

53. The signal receiver of claim 43, wherein said alert output from said human observable alert module is proportional to the strength of the signal detected.

54. The signal receiver of claim 53, wherein the intensity of said alert is adjustable via the signal receiver configuration unit.

55. A signal receiver for use in locating a wire within in a multi-wire electrical system, comprising:
a signal receiver module to receive signals from one or more wires and detect only unique tracing signals;
a human observable alert module configured to output a human observable alert in response to detecting a unique tracing signal; and
a signal strength threshold setting used to set a signal strength threshold wherein the human observable alert module generates a human observable alert only for detected signals with a signal strength greater than said signal strength threshold.

56. The signal receiver of claim 55, wherein the signal strength threshold is fixed.

57. The signal receiver of claim 55, wherein the signal strength threshold is user configurable.

58. The signal receiver of claim 55, wherein said alert output from said human observable alert module is proportional to the strength of the signal detected.

59. The signal receiver of claim 55, further comprising a human observable alert sensitivity setting wherein the strength of a human observable alert is based upon said human observable alert sensitivity setting.

60. The signal receiver of claim 59, wherein the human observable alert sensitivity setting is fixed.

61. The signal receiver of claim 59, wherein the human observable alert sensitivity setting is user configurable.

62. The signal receiver of claim 59, wherein the intensity of said human observable alert is scaled by the human observable alert sensitivity setting.

63. The signal receiver of claim 55, wherein the unique signal detected by the signal receiver module includes at least one of a digital code, a unique identifier, voice message, a prerecorded voice message, and a user recorded voice message.

64. The signal receiver of claim 55, wherein the unique signal detected by the signal receiver module includes at least one of a simulated voice message, modulation characteristics based upon a unique identifier, frequency characteristics based upon a unique identifier, frequency characteristics based upon a unique assigned frequency, and amplitude characteristics based upon a unique identifier.

65. The signal receiver of claim 55, wherein the alert from the human observable alert module includes at least one of an audible alert, a visual alert, a voice message, and a vibratory alert.

66. The signal receiver of claim 65, wherein said visual alert comprises: flashing lights; sequentially activated lights; flashing LEDs; sequentially activated LEDs; display of alphanumeric messages presented via an LCD display; display of graphical messages presented via an LCD display; display of alphanumeric messages presented via an LED display; and display of graphical messages presented via an LED display.

67. The signal receiver of claim 66, wherein said visual alert further comprises an alphanumeric display containing the unique identifier of a detected signal.
